(19) United States
(12) Patent Application Publication
(10) Pub. No.: US 2013/0009160 A1
(43) Pub. Date: Jan. 10, 2013

(54) ACTIVE MATRIX SUBSTRATE

(75) Inventors: Hiromitsu Katsui, Osaka (JP); Wataru Nakamura, Osaka (JP); Kenichi Kitoh, Osaka (JP)

(73) Assignee: SHARP KABUSHIKI KAISHA, Osaka (JP)

(21) Appl. No.: 13/635,200

(22) PCT Filed: Dec. 7, 2010
(86) PCT No.: PCT/JP2010/007105

§ 371 Date: Sep. 14, 2012

(30) Foreign Application Priority Data
Mar. 19, 2010 (JP) 2010-064758

(51) Int. Cl. H01L 27/15

(52) U.S. Cl. 257/59; 257/E27.121

(57) ABSTRACT

Disposed on an insulating substrate (10a) are a plurality of TFTs arranged in a matrix, each including a drain electrode (18b) in which a first conductive layer (16b) and a second conductive layer (17bb) are laminated in this order; an interlayer insulating film (21) deposited on each of the TFTs, in which a plurality of contact holes (21a) reaching to the respective drain electrodes (18b) are formed; and a plurality of pixel electrodes (22a) disposed on the interlayer insulating film (21) in a matrix, each connected to a corresponding drain electrode (18b) via a corresponding contact hole (21a), being susceptible to an electric corrosion reaction with the second conductive layer (17bb). At a side of the drain electrode, which is connected to the pixel electrode (22a), a top surface of the first conductive layer (16b) is exposed from the second conductive layer (17bb). The interlayer insulating film (21) is disposed to cover the second conductive layer (17bb).

### TECHNICAL FIELD

The present invention relates to an active matrix substrate, and specifically, to an active matrix substrate using an aluminum film and an ITO (Indium Tin Oxide) film.

### BACKGROUND ART

An active matrix substrate is provided with a plurality of gate lines disposed so as to extend in parallel with each other, a plurality of source lines disposed so as to extend in parallel with each other in a direction orthogonal to the respective gate lines, a plurality of thin film transistors (hereinafter also referred to as “TFTs”) disposed at respective intersections of the gate lines and the source lines, an interlayer insulating film disposed so as to cover the respective TFTs, and a plurality of pixel electrodes disposed on the interlayer insulating film in a matrix and connected to the respective TFTs, for example. In the active matrix substrate having this configuration, in many cases, the pixel electrodes are formed using an ITO film, which is a common transparent conductive film, and display wiring lines such as the gate lines and the source lines are formed using a multilayer metal film that contains a low-resistance metal film such as an aluminum film.

Patent Document 1, for example, discloses a method of manufacturing a liquid crystal display device, including: forming a through hole (which corresponds to a contact hole to be described later) in an interlayer insulating film such that at least part of an outer edge of a drain lead-out electrode is exposed therefrom; removing a low-resistance metal film on the drain lead-out electrode, which is exposed in the through hole, by wet etching; and forming a picture element electrode (which corresponds to the pixel electrode described above) on the interlayer insulating film and the drain lead-out electrode from which the low-resistance metal film is removed.

Patent Document 2 discloses a method of manufacturing a liquid crystal display device in which a source wiring line and a drain wiring line that are formed by depositing a heat-resistant metal layer and an aluminum layer are employed, and an undercut in a passivation insulating layer (which corresponds to the interlayer insulating film described above), which is generated when the aluminum layer in an opening on a drain electrode is removed by side etching, is eliminated by an additional manufacturing step of making the opening larger.

### RELATED ART DOCUMENTS

### Patent Documents

Patent Document 1: Japanese Patent Application Laid-Open Publication No. 2000-199917
Patent Document 2: Japanese Patent Application Laid-Open Publication No. 2005

### SUMMARY OF THE INVENTION

### Problems to be Solved by the Invention

FIG. 23 is a cross-sectional view of a pixel contact portion in a conventional active matrix substrate 130. FIG. 24 is a cross-sectional view of an S-G contact portion in the active matrix substrate 130.

As shown in FIGS. 23 and 24, the active matrix substrate 130 is provided with a capacitance line 111a and a source line lead-out wiring line 111b that are respectively disposed in the pixel contact portion and the S-G contact portion on an insulating substrate 110, a gate insulating film 112 disposed so as to cover the capacitance line 111a and the source line lead-out wiring line 111b, a semiconductor layer 115a constituted of an intrinsic amorphous silicon layer 113a and an n⁺ amorphous silicon layer 114a that are disposed on the gate insulating film 112 in an island shape, a semiconductor layer 115b constituted of an intrinsic amorphous silicon layer 113b and an n⁺ amorphous silicon layer 114b, a drain electrode 118a constituted of a titanium layer 116a and an aluminum layer 117a that are disposed on the semiconductor layer 115a, a source line 118b constituted of a titanium layer 116b and an aluminum layer 117b disposed on the semiconductor layer 115b, an interlayer insulating film 121 constituted of a first interlayer insulating film 119 and a second interlayer insulating film 120 that are disposed so as to cover the drain electrode 118a and the source line 118b, and a pixel electrode 122a and a transparent conductive layer 122b constituted of an ITO layer that is disposed on the interlayer insulating film 121.

As shown in FIG. 23, at the pixel contact portion in the active matrix substrate 130, the drain electrode 118a and the pixel electrode 122a are connected via a contact hole 121a that is formed in the interlayer insulating film 121. As shown in FIG. 24, at the S-G contact portion, the source line 118b and the source line lead-out wiring line 111b are connected via the transparent conductive layer 122b that is disposed in a contact hole 121b formed in a multilayer film of the interlayer insulating film 121 and the gate insulating film 112. Here, to prevent an electric corrosion reaction caused by a contact between the aluminum layer 117a and the pixel electrode 122a and by a contact between the aluminum layer 117b and the transparent conductive layer 122b, respective edge faces of the aluminum layer 117a and the aluminum layer 117b need to be receded in part of respective inner walls of the contact holes 121a and 121b, in the same manner as the manufacturing method disclosed in Patent Document 1. As a result, an overhang in an eaves shape is formed in part of the respective inner walls of the contact holes 121a and 121b. Consequently, the edge face of the aluminum layer 117a is exposed to a liquid crystal material, and the edge face of the aluminum layer 117b is exposed to the air, which may cause corrosion of the aluminum layer 117a and the aluminum layer 117b. Therefore, this configuration needs to be improved.

The present invention was made in view of such problems, and aims at suppressing an electric corrosion reaction, and also, suppressing corrosion of a drain electrode.

### Means for Solving the Problems

In order to achieve the above objective, the present invention is configured such that, at a side of a drain electrode, which is connected to a pixel electrode, a top surface of a first conductive layer is exposed from a second conductive layer, and the second conductive layer is covered by an interlayer insulating film.

Specifically, an active matrix substrate according to the present invention includes: a plurality of thin film transistors disposed on an insulating substrate in a matrix, each of which has a source electrode and a drain electrode formed by laminating a first conductive layer and a second conductive layer in this order; an interlayer insulating film that is deposited on the respective thin film transistors, the interlayer insulating film having a plurality of contact holes, each of which reach to a respective drain electrode, formed therein; and a plurality of pixel electrodes disposed on the interlayer insulating film in a matrix, each of which is connected to a respective drain electrode via a corresponding contact hole, the plurality of pixel electrodes being susceptible to an electric corrosion reaction with the second conductive layer, wherein, at a side of each drain electrode, which is connected to a corresponding pixel electrode, a top surface of the first conductive layer is exposed from the second conductive layer, and wherein the interlayer insulating film is disposed so as to cover the second conductive layer.

According to this configuration, in the drain electrodes, each of which is formed by laminating the first conductive layer and the second conductive layer in this order, at a side thereof connected to each pixel electrode, the top surface of the first conductive layer is exposed from the second conductive layer, and the second conductive layer is covered by the interlayer insulating film. Therefore, the second conductive layer does not come into contact with the pixel electrodes, thereby suppressing a possible electric corrosion reaction between the drain electrodes and the pixel electrodes. Also, because the second conductive layer that constitutes the drain electrodes is covered by the interlayer insulating film, even when the active matrix substrate is used to constitute a liquid crystal display device together with an opposite substrate and a liquid crystal layer that is made of a liquid crystal material, the second conductive layer can be prevented from being exposed to the liquid crystal material, thereby suppressing corrosion of the second conductive layer. As a result, an electric corrosion reaction between the drain electrodes and the pixel electrodes is suppressed, and also, corrosion of the second conductive layer is suppressed. Therefore, in the active matrix substrate, an electric corrosion reaction is suppressed, and also, corrosion of the drain electrodes is suppressed.

The second conductive layer may be formed of an aluminum film or an aluminum alloy film, and the respective pixel electrodes may be formed of an ITO (Indium Tin Oxide) film.

According to this configuration, the second conductive layer is formed of the aluminum film or the aluminum alloy film, and the respective pixel electrodes are formed of the ITO (Indium Tin Oxide) film. Therefore, a possible electric corrosion reaction between the drain electrodes and the pixel electrodes is specifically suppressed.

The active matrix substrate may include: a gate electrode disposed in each of the thin film transistors so as to overlap the source electrode and the drain electrode; a first wiring line formed of a same material and disposed in a same layer as those of the gate electrode; a gate insulating film disposed so as to cover the first wiring line; and a second wiring line formed of a same material and disposed in a same layer as those of the source electrode and the drain electrode, wherein the first wiring line and the second wiring line are connected through a transparent conductive layer that is formed of a same material and is disposed in a same layer as those of the respective pixel electrodes, the transparent conductive layer being formed in a contact hole formed in a multilayer film of the gate insulating film and the interlayer insulating film, wherein, at a side of the second wiring line, which is connected to the transparent conductive layer, a top surface of the first conductive layer is exposed from the second conductive layer; and wherein the interlayer insulating film is disposed so as to cover the second conductive layer on the second wiring line.

According to this configuration, in the second wiring line that is formed of the same material and is disposed on the same layer as those of the source electrode and the drain electrode (in other words, the second wiring line is formed by laminating the first conductive layer and the second conductive layer in this order), at a side thereof connected to the transparent conductive layer, a top surface of the first conductive layer is exposed from the second conductive layer, and the second conductive layer is covered by the interlayer insulting film. Therefore, the second conductive layer does not come into contact with the transparent conductive layer, thereby suppressing a possible electric corrosion reaction in a connection structure of the first wiring line and the second wiring line through the transparent conductive layer. Also, because the second conductive layer that constitutes the second wiring line is covered by the interlayer insulting film, the second conductive layer can be prevented from being exposed to the air, thereby suppressing corrosion of the second conductive layer. As a result, an electric corrosion reaction caused by the second wiring line is suppressed, and also, corrosion of the second wiring line is suppressed.

The second wiring line may be a source line that is connected to the corresponding source electrode, and the first wiring line may be a source line lead-out wiring line that is connected to the source line.

According to this configuration, the second wiring line is the source line that is connected to the source electrode, and the first wiring line is the source line lead-out wiring line that is connected to the source line. Therefore, the source line and the source line lead-out wiring line are specifically connected through the transparent conductive layer that is formed in the contact hole in the interlayer insulating film, and also, an electric corrosion reaction and corrosion in the source line are suppressed.

The active matrix substrate may include: a semiconductor layer disposed in each of the thin film transistors so as to overlap the gate electrode through the gate insulating film, the semiconductor layer also overlapping the source electrode and the drain electrode; and a capacitance line formed of a same material and disposed on a same layer as those of the gate electrode so as to overlap a connecting portion of the drain electrode and the respective pixel electrodes through the gate insulating film, wherein, between the gate insulating film and the connecting portion of the drain electrode and the respective pixel electrode, an etching stopper layer may be formed of a same material and be disposed on a same layer as those of the semiconductor layer.

According to this configuration, the etching stopper layer formed of the same material and disposed on the same layer as those of the semiconductor layer is disposed between the gate insulating film and the connecting portion of the drain electrode and the respective pixel electrodes. Therefore, when the contact hole is formed in the multilayer film of the gate insulating film and the interlayer insulating film, the gate insulating film becomes less likely to be exposed to etching. As a result, a short circuit problem at an auxiliary capacitance that is constituted of the capacitance line, the drain electrode, and the gate insulating film therebetween is suppressed.

The interlayer insulating film may include a first interlayer insulating film formed of an inorganic insulating film, and a second interlayer insulating film formed of an organic insulating film on the first interlayer insulating film.

According to this configuration, the interlayer insulating film is provided with the first interlayer insulating film that is formed relatively thin using the inorganic insulating film, and the second interlayer insulating film that is formed relatively thick on the first interlayer insulating film using the organic insulating film. Therefore, the top surface of the interlayer insulating film is planarized.

### Effects of the Invention

According to the present invention, at a side of the drain electrode, which is connected to a corresponding pixel electrode, the top surface of the first conductive layer is exposed from the second conductive layer, and the second conductive layer is covered by the interlayer insulating film. This makes it possible to suppress an electric corrosion reaction, and to suppress corrosion of the drain electrode.

### BRIEF DESCRIPTION OF THE DRAWINGS

FIG. 1 is a perspective view showing a liquid crystal display device that is provided with an active matrix substrate according to Embodiment 1.

FIG. 2 is a plan view showing each pixel in the active matrix substrate according to Embodiment 1.

FIG. 3 is a plan view showing an S-G contact portion in the active matrix substrate according to Embodiment 1.

FIG. 4 is a first explanatory figure showing a process of manufacturing a TFT in the active matrix substrate according to Embodiment 1 in a cross-sectional view.

FIG. 5 is a second explanatory figure showing a process of manufacturing the TFT in the active matrix substrate, which is performed after the process shown in FIG. 4, in a cross-sectional view.

FIG. 6 is a first explanatory figure showing a process of manufacturing a pixel contact portion in the active matrix substrate according to Embodiment 1 in a cross-sectional view.

FIG. 7 is a second explanatory figure showing a process of manufacturing the pixel contact portion in the active matrix substrate, which is performed after the process shown in FIG. 6, in a cross-sectional view.

FIG. 8 is a first explanatory figure showing a process of manufacturing an S-G contact portion in the active matrix substrate according to Embodiment 1 in a cross-sectional view.

FIG. 9 is a second explanatory figure showing a process of manufacturing the S-G contact portion in the active matrix substrate, which is performed after the process shown in FIG. 8, in a cross-sectional view.

FIG. 10 is an enlarged plan view of the S-G contact portion in the active matrix substrate according to Embodiment 1.

FIG. 11 is an enlarged plan view of an S-G contact portion in Modification Example 1 of the active matrix substrate according to Embodiment 1.

FIG. 12 is a cross-sectional view of the S-G contact portion along the line XII-XII in FIG. 11 in Modification Example 1 of the active matrix substrate.

FIG. 13 is an enlarged plan view of an S-G contact portion in Modification Example 2 of the active matrix substrate according to Embodiment 1.

FIG. 14 is a cross-sectional view of the S-G contact portion along the line XIV-XIV in FIG. 13 in Modification Example 2 of the active matrix substrate.

FIG. 15 is an enlarged plan view of the pixel contact portion in the active matrix substrate according to Embodiment 1.

FIG. 16 is a plan view showing a terminal of a source line in the active matrix substrate according to Embodiment 1.

FIG. 17 is a plan view showing a modification example of the terminal of the source line in the active matrix substrate according to Embodiment 1.

FIG. 18 is an explanatory figure showing a process of manufacturing an opposite substrate disposed to face the active matrix substrate according to Embodiment 1 in a cross-sectional view.

FIG. 19 is a first explanatory figure showing a process of manufacturing an active matrix substrate according to Embodiment 2 in a cross-sectional view.

FIG. 20 is a second explanatory figure showing a process of manufacturing the active matrix substrate, which is performed after the process shown in FIG. 19, in a cross-sectional view.

FIG. 21 is a second explanatory figure showing a process of manufacturing an active matrix substrate according to Embodiment 3 in a cross-sectional view.

FIG. 22 is a second explanatory figure showing a process of manufacturing the active matrix substrate, which is performed after the process shown in FIG. 21, in a cross-sectional view.

FIG. 23 is a cross-sectional view of a pixel contact portion in a conventional active matrix substrate.

FIG. 24 is a cross-sectional view of an S-G contact portion of the conventional active matrix substrate.

### DETAILED DESCRIPTION OF EMBODIMENTS

Embodiments of the present invention will be described in detail with reference to the figures. The present invention is not limited to each of the embodiments described below.

### Embodiment 1

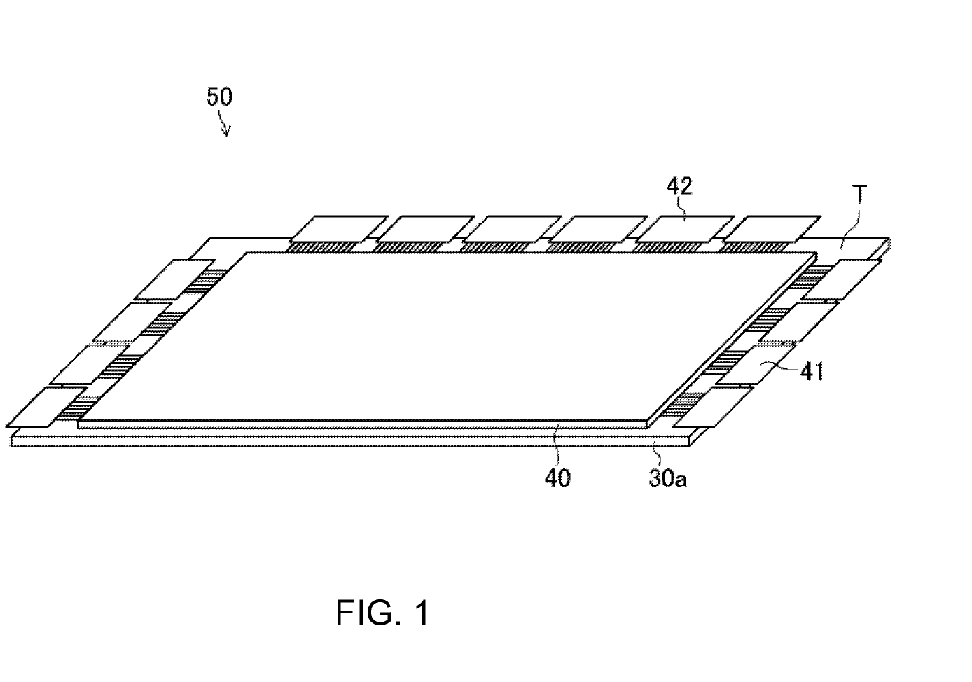

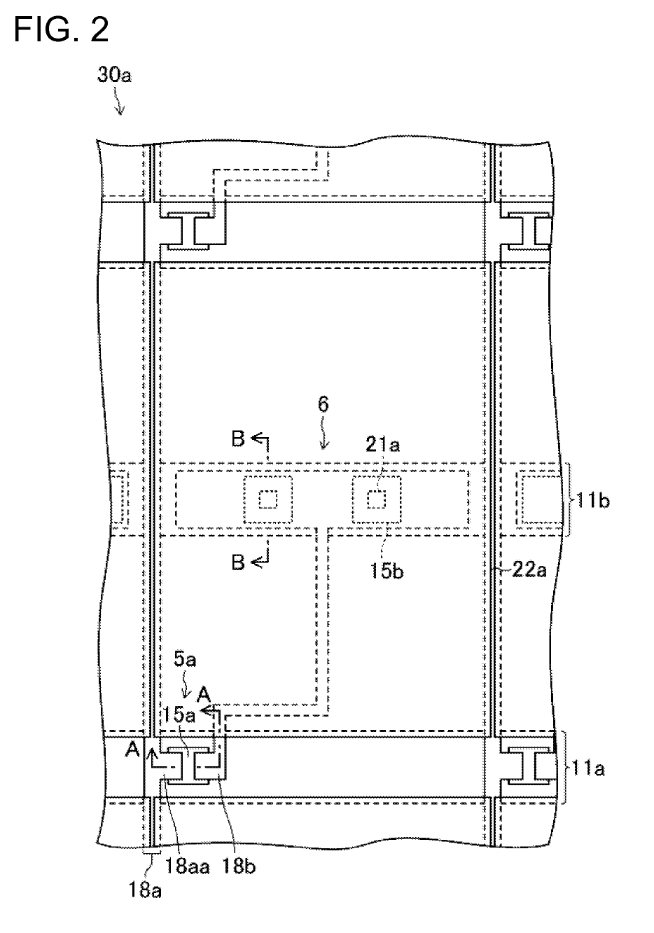

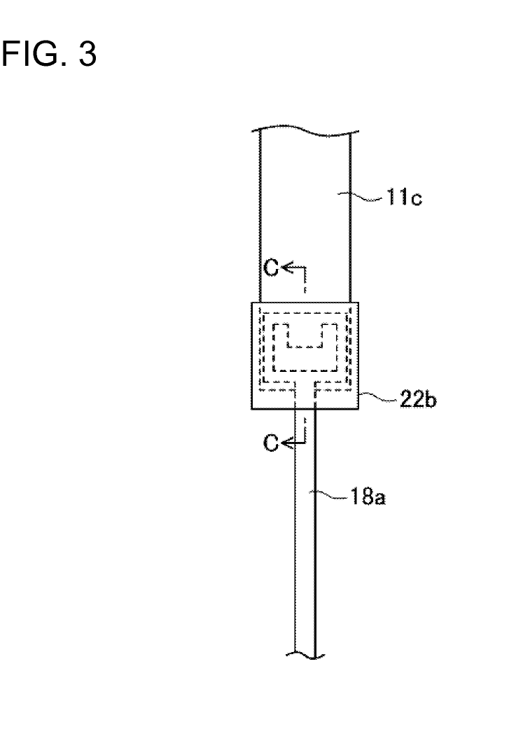

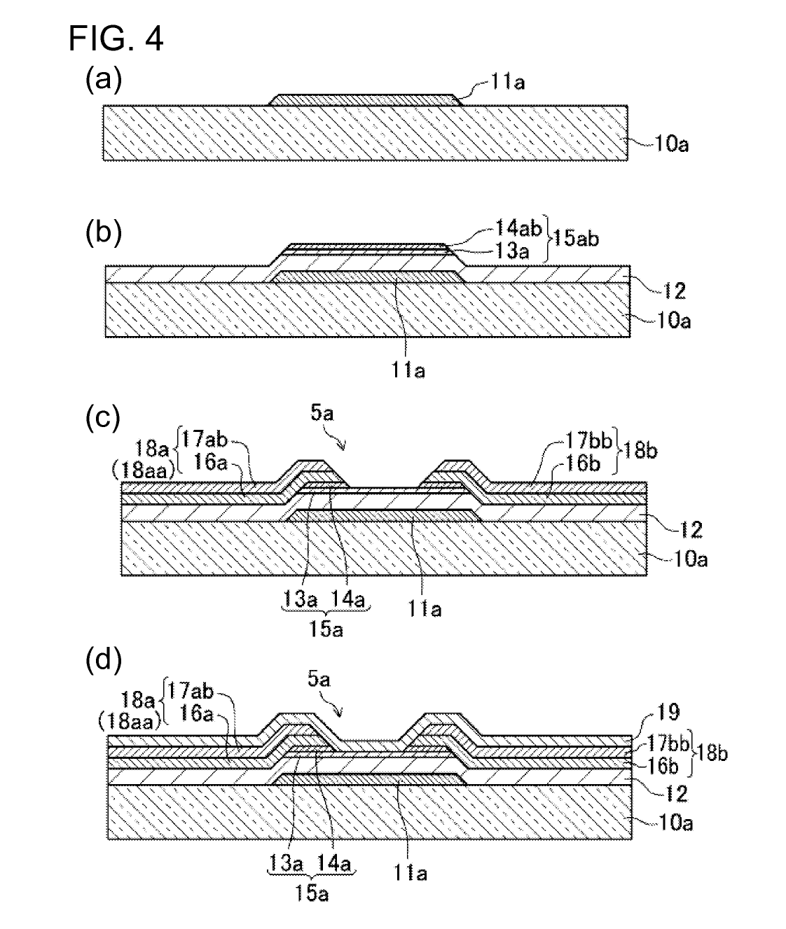

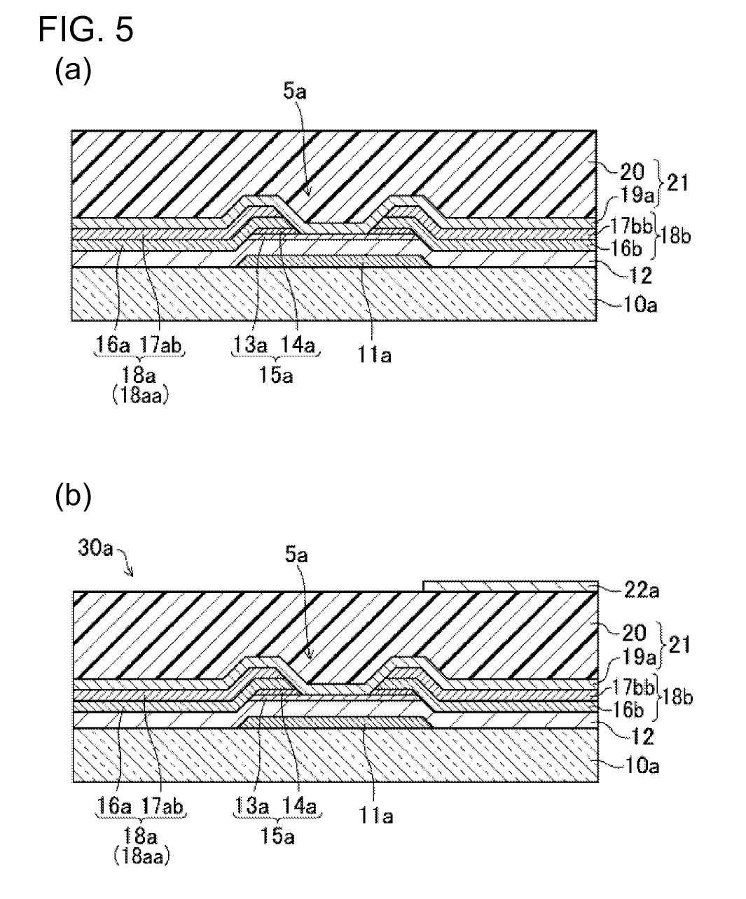

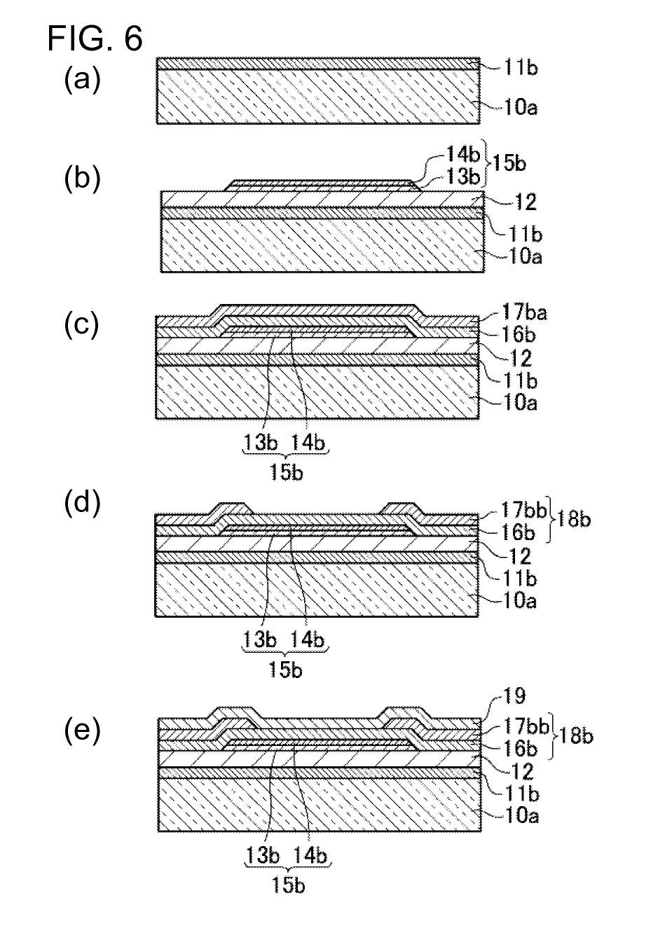

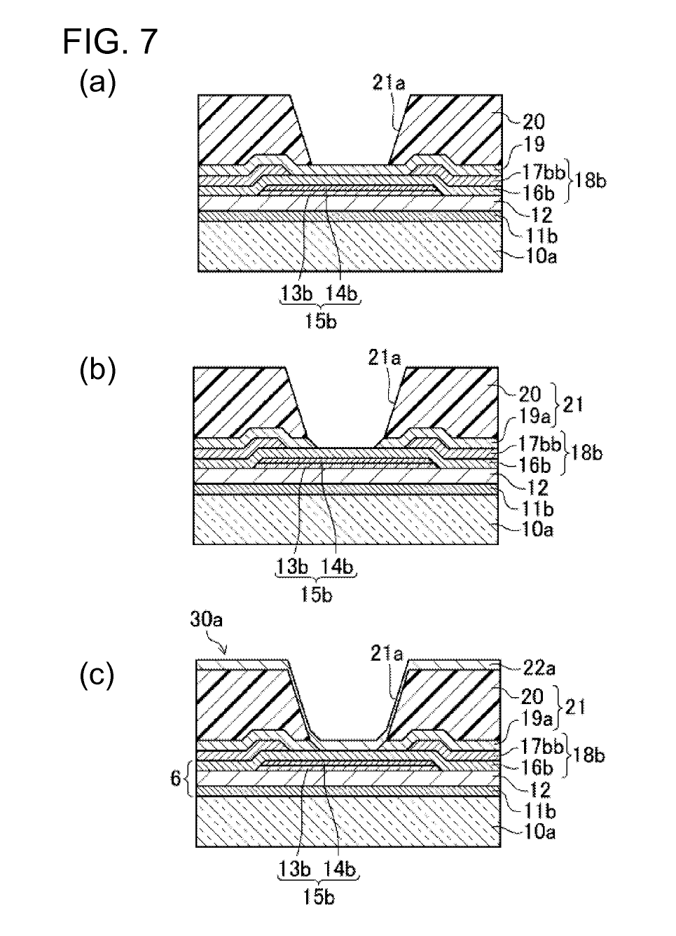

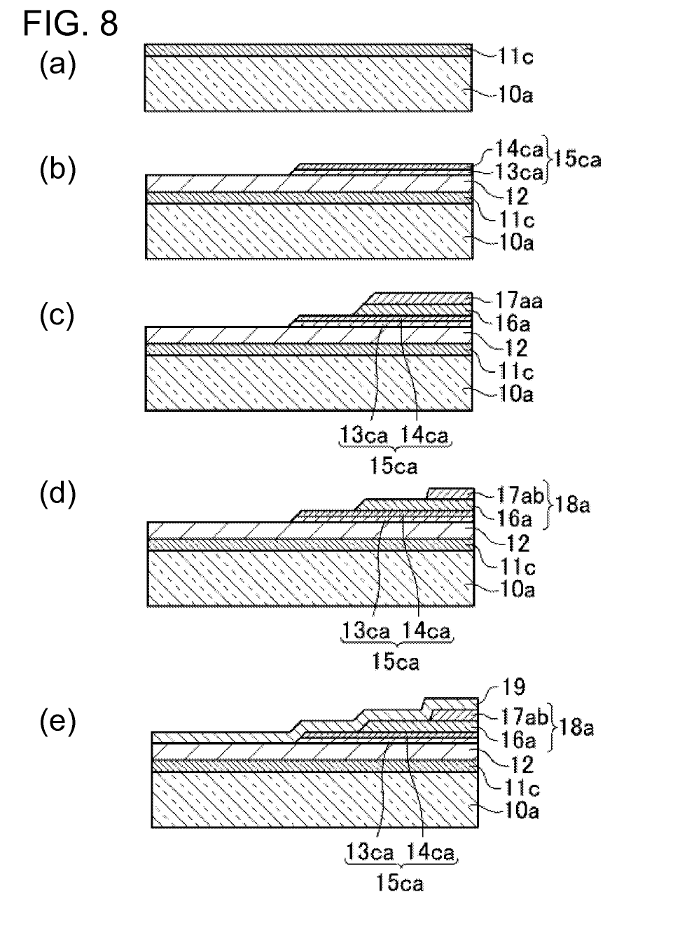

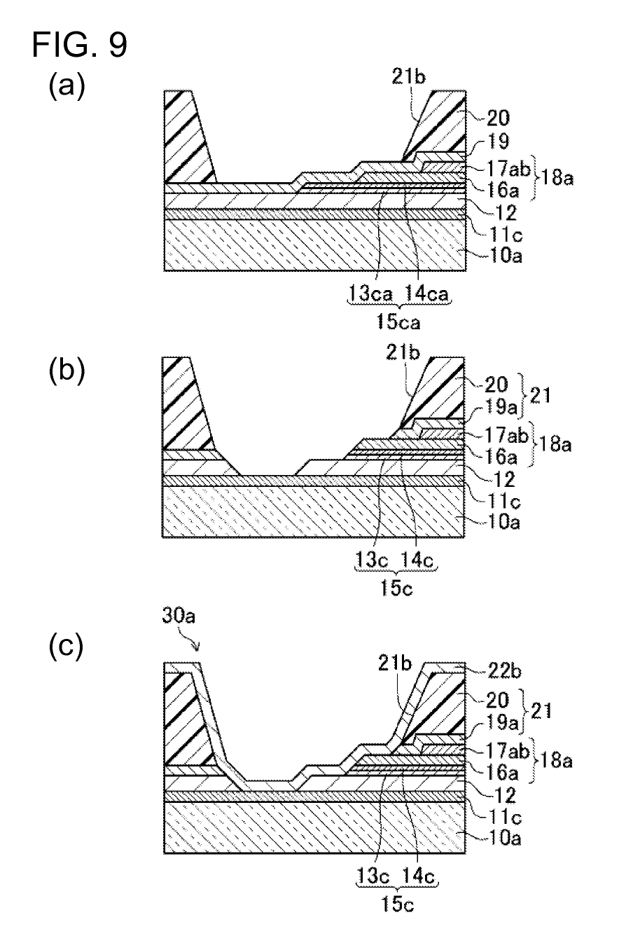

FIGS. 1 to 18 show Embodiment 1 of an active matrix substrate according to the present invention. More specifically, FIG. 1 is a perspective view showing a liquid crystal display device 50 that is provided with an active matrix substrate 30a of the present embodiment. FIG. 2 is a plan view showing each pixel in the active matrix substrate 30a. FIG. 3 is a plan view showing an S-G contact portion in the active matrix substrate 30a. FIGS. 4 and 5 are explanatory figures showing a process of manufacturing a TFT in the active matrix substrate 30a in a cross-sectional view. FIGS. 6 and 7 are explanatory figures showing a process of manufacturing a pixel contact portion in the active matrix substrate 30a in a cross-sectional view. FIGS. 8 and 9 are explanatory figures showing a process of manufacturing an S-G contact portion in the active matrix substrate 30a in a cross-sectional view. FIGS. 5(b), 7(c), and 9(c) correspond to respective cross-sectional views of the active matrix substrate 30a along the lines A-A and B-B in FIG. 2, and the line C-C in FIG. 3.

As shown in FIG. 1, the liquid crystal display device 50 is provided with the active matrix substrate 30a and an opposite substrate 40 disposed to face each other, and a liquid crystal layer (not shown) that is sealed between the active matrix substrate 30a and the opposite substrate 40 by a sealing material (not shown). As shown in FIG. 1, in the liquid crystal display device 50, a plurality of gate-side TCPs (Tape Carrier Packages) 41 and a plurality of source-side TCPs 42 are attached through an ACF (Anisotropic Conductive Film) on a terminal region T in the active matrix substrate 30a that protrudes from the opposite substrate 40. On the respective gate-side TCPs 41, gate driver ICs (Integrated Circuits) are mounted, and on the respective source-side TCPs 42, source driver ICs are mounted.

As shown in FIGS. 2 and 5(b), the active matrix substrate 30a is provided with a plurality of gate lines 11a disposed on an insulating substrate 10a so as to extend in parallel with each other, a plurality of capacitance lines 11b disposed between the respective gate lines 11a and extended in parallel with each other, a plurality of source lines 18a disposed so as to extend in parallel with each other in a direction orthogonal to the respective gate lines 11a, a plurality of TFTs 5a disposed at respective intersections of the gate lines 11a and the source lines 18a, i.e., in respective pixels, an interlayer insulating film 21 constituted of a first interlayer insulating film 19a and a second interlayer insulating film 20 that are disposed on the respective TFTs 5a, a plurality of pixel electrodes 22a disposed on the interlayer insulating film 21 in a matrix, and an alignment film (not shown) disposed to cover the respective pixel electrodes 22a.

The gate lines 11a are led out to the terminal region T, and are connected to the gate-side TCPs 41 as shown in FIG. 1.

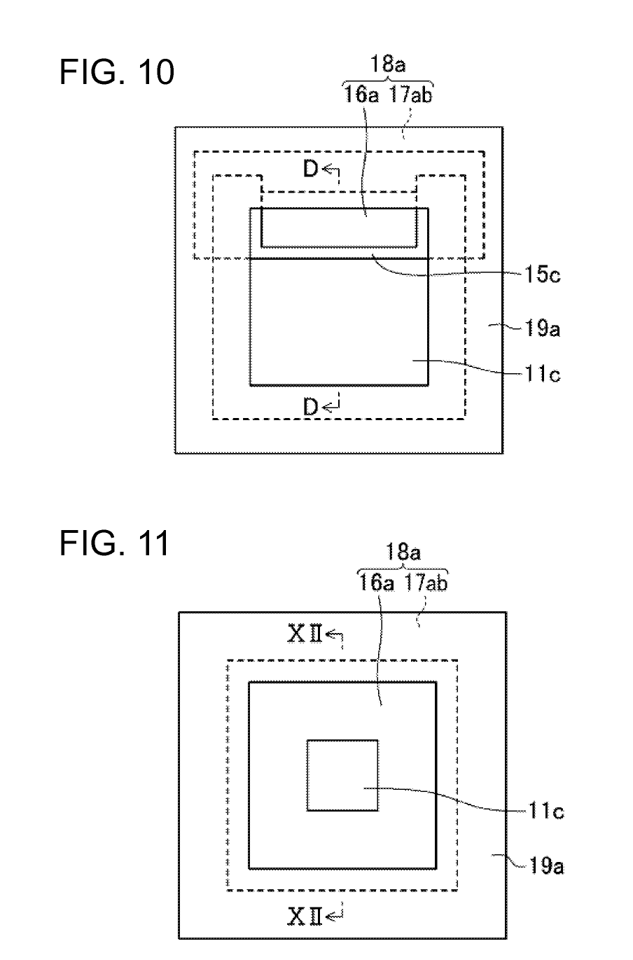

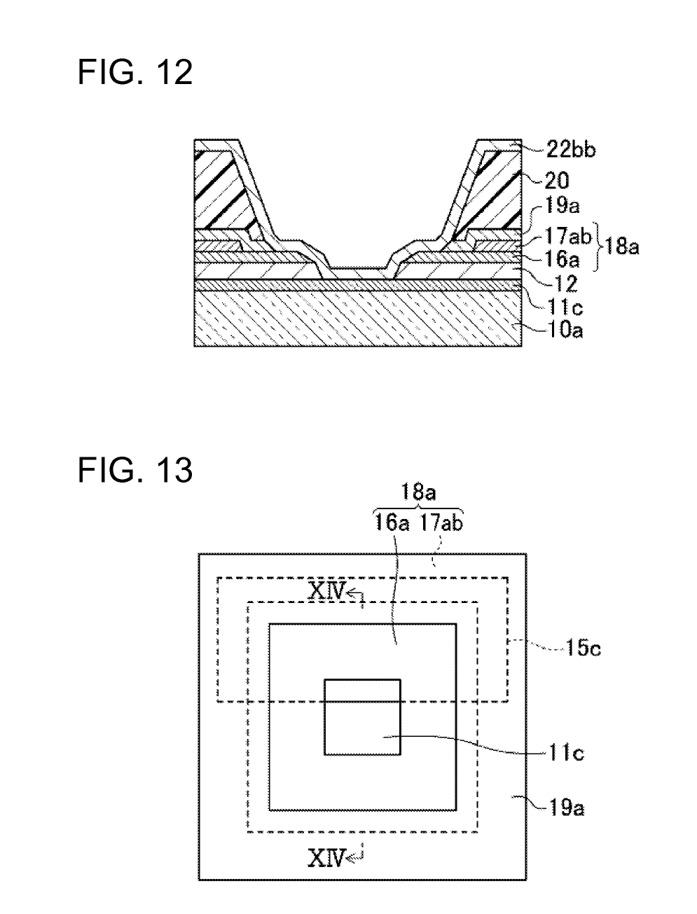

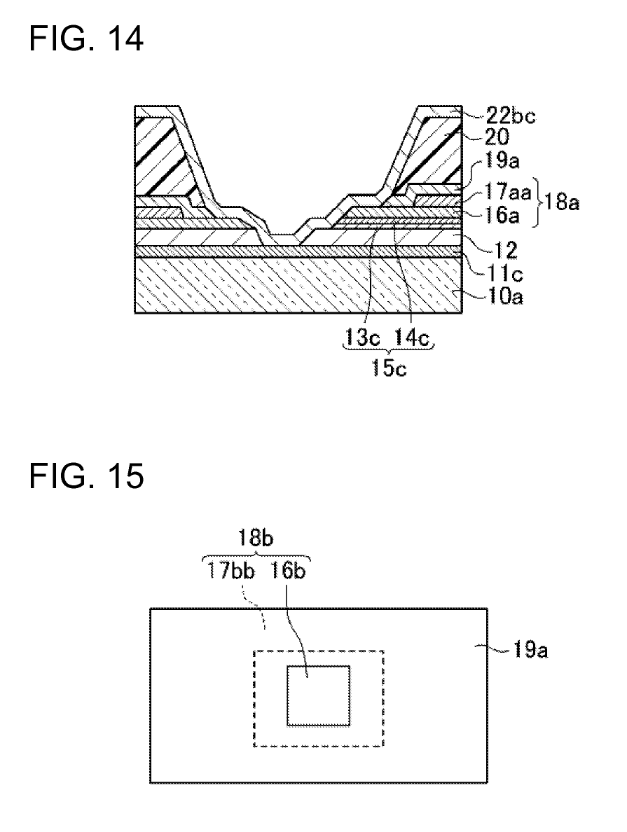

FIG. 10 is an enlarged plan view of an S-G contact portion in the active matrix substrate 30a. In FIG. 10, the second interlayer insulating film (20) and the transparent conductive layer (22a) that are provided on the S-G contact portion are not shown, and a source line lead-out wiring line 11c, a semiconductor layer 15c, the source line 18a, and the first interlayer insulating film 19a are shown therein. A cross-sectional view along the line D-D in FIG. 10 corresponds to a cross-sectional view shown in FIG. 9(c). FIG. 11 is an enlarged plan view of an S-G contact portion in Modification Example 1 of the active matrix substrate 30a. FIG. 12 is a cross-sectional view of the S-G contact portion along the line XII-XII in FIG. 11. FIG. 13 is an enlarged plan view of an S-G contact portion in Modification Example 2 of the active matrix substrate 30a. FIG. 14 is a cross-sectional view of the S-G contact portion along the line XIV-XIV in FIG. 13.

The source line (second wiring line) 18a is led out to the terminal region T. As shown in FIGS. 1, 3, 9(c), and 10, in the terminal region T, the source line 18a is connected to the source line lead-out wiring line (first wiring line) 11c through a transparent conductive layer 22b that is disposed in a contact hole 21b, and the source line lead-out wiring line 11c is connected to the source-side TCP 42.

As shown in FIGS. 5(b), 9(c), and 10, the source line 18a is provided with a first conductive layer 16a and a second conductive layer 17ab deposited on the first conductive layer 16a. At a side of the source line 18a, which is connected to the transparent conductive layer 22b, a top surface of the first conductive layer 16a is exposed from the second conductive layer 17ab, and the interlayer insulating film 21 (first interlayer insulating film 19a) is disposed so as to cover the second conductive layer 17ab.

As shown in FIGS. 9(c) and 10 described above, the source line 18a and the transparent conductive layer 22b may have a connection structure in which a connecting portion of the source line 18a has a U-shaped opening, and the semiconductor layer 15c that is constituted of an intrinsic amorphous silicon layer 13c and an n⁺ amorphous silicon layer 14c is interposed therebetween. Alternatively, the source line 18a and the transparent conductive layer 22b may have connection structures as follows: as shown in FIGS. 11 and 12, the connecting portion of the source line 18a has a rectangular-shaped opening; as shown in FIGS. 13 and 14, the connecting portion of the source line 18a has a rectangular-shaped opening, and the semiconductor layer 15c that is constituted of the intrinsic amorphous silicon layer 13c and the n⁺ amorphous silicon layer 14c is interposed therebetween; and the like, for example.

As shown in FIGS. 2 and 5(b), the TFT 5a is provided with the gate electrode (11a) disposed on the insulating substrate 10a, a gate insulating film 12 disposed so as to cover the gate electrode (11a), a semiconductor layer 15a disposed in an island shape on the gate insulating film 12 at a location that corresponds to the gate electrode (11a), and a source electrode 18aa and a drain electrode 18b disposed on the semiconductor layer 15a so as to face each other.

As shown in FIG. 2, the gate electrode (11a) is part of the gate line 11a.

As shown in FIG. 5(b), the semiconductor layer 15a is provided with an intrinsic amorphous silicon layer 13a and an n⁺ amorphous silicon layer 14a. The intrinsic amorphous silicon layer 13a has a channel region. The n⁺ amorphous silicon layer 14a is disposed on the intrinsic amorphous silicon layer 13a so as to have the channel region exposed therefrom, and the n⁺ amorphous silicon layer 14a is connected to the source electrode 18aa and the drain electrode 18b.

As shown in FIG. 2, the source electrode 18aa is a portion of the source line 18a that protrudes to the side.

FIG. 15 is an enlarged plan view of the pixel contact portion in the active matrix substrate 30a. In FIG. 15, the pixel electrode (22a) provided on the pixel contact portion is not shown, and the drain electrode 18b and the first interlayer insulating film 19a are shown therein.

As shown in FIGS. 2 and 5(b), the drain electrode 18b is connected to the pixel electrode 22a via a contact hole 21a that is formed in the interlayer insulating film 21, and also, as shown in FIGS. 2 and 7(c), the drain electrode 18b constitutes an auxiliary capacitance 6 by overlapping the capacitance line 11b through the gate insulating film 12. As shown in FIGS. 2 and 5(b), immediately below the contact hole 21a, a semiconductor layer (etching stopper layer) 15b constituted of an intrinsic amorphous silicon layer 13b and an n⁺ amorphous silicon layer 14b is disposed. If the first conductive layer 16a of the source line 18a has a sufficient resistance against dry etching, the semiconductor layer (etching stopper layer) 15b does not need to be provided, and it can therefore be omitted.

As shown in FIGS. 5(b), 7(c), and 15, the drain electrode 18b is provided with a first conductive layer 16b and a second conductive layer 17bb that is deposited on the first conductive layer 16b. As shown in FIGS. 7(c) and 15, at a side of the drain electrode 18b, which is connected to the pixel electrode, a top surface of the first conductive layer 16b is exposed from the second conductive layer 17bb, and the interlayer insulating film 21 (first interlayer insulating film 19a) is disposed so as to cover the second conductive layer 17bb.

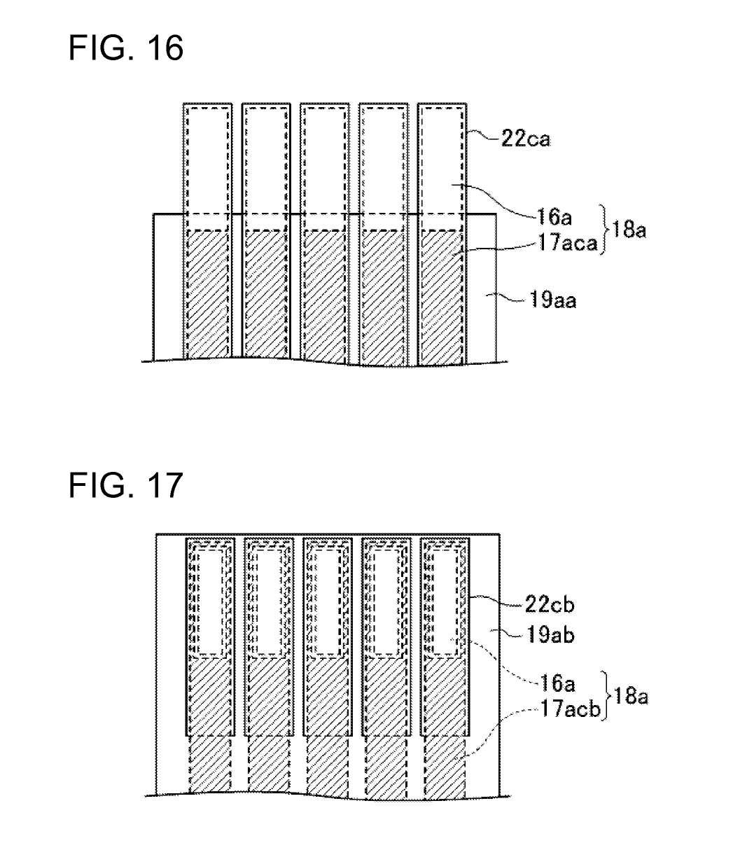

In the present embodiment, a structure in which the source line 18a is connected to the source-side TCP (42) through the source line lead-out wiring line 11c is described as an example. Alternatively, as shown in FIGS. 16 and 17, the source line 18a may be led out directly and connected directly to the source-side TCP 42. FIG. 16 is a plan view showing source line terminals when the source lines 18a are led out directly. FIG. 17 is a plan view showing a modification example of the source line terminals.

More specifically, in the source line terminals shown in FIG. 16, the respective source lines 18a are provided with the first conductive layer 16a and a second conductive layer 17aca that is deposited on the first conductive layer 16a. Top surfaces of respective ends of the first conductive layers 16a are exposed from the respective second conductive layers 17aca. A first interlayer insulating film 19aa is disposed so as to cover the respective second conductive layers 17aca. Transparent conductive layers 22ca are disposed so as to cover the respective first conductive layers 16a that are exposed from the first interlayer insulating film 19aa.

In the source line terminals shown in FIG. 17, the respective source lines 18a are provided with the first conductive layer 16a and a second conductive layer 17acb that is deposited on the first conductive layer 16a. At ends of the respective second conductive layers 17acb, openings in which top surfaces of the respective first conductive layers 16a are exposed therefrom are formed, respectively. A first interlayer insulating film 19ab is disposed so as to cover the respective second conductive layers 17acb. Transparent conductive layers 22cb are disposed so as to cover the respective first conductive layers 16a that are exposed from the first interlayer insulating film 19ab.

The gate line 11a may be connected to a gate line lead-out line that is formed of the same material and that is disposed on the same layer as those of the source line 16a, using the S-G contact portion described above, and a terminal of the gate line lead-out line may have the same configuration as that of the source line terminal shown in FIGS. 16 and 17.

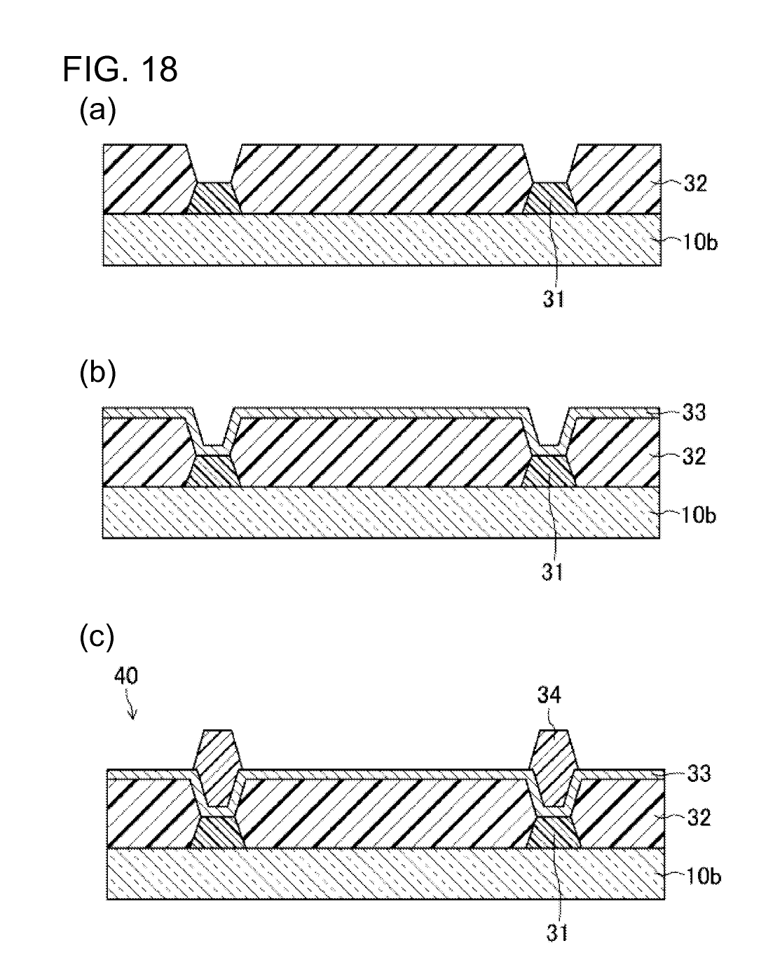

FIG. 18 is an explanatory figure showing a process of manufacturing the opposite substrate 40 disposed so as to face the active matrix substrate 30a in a cross-sectional view.

As shown in FIG. 18(c), the opposite substrate 40 is provided with a black matrix 31 disposed on an insulating substrate 10b in a grid pattern, a plurality of colored layers 32 such as red layers, green layers, and blue layers respectively disposed in the respective grids of the black matrix 31, a common electrode 33 disposed so as to cover the black matrix 31 and the respective colored layers 32, photospacers 34 in a columnar shape disposed on the common electrode 33, and an alignment film (not shown) disposed so as to cover the common electrode 33.

The liquid crystal layer described above is constituted of a nematic liquid crystal material that has electrooptic characteristics, and the like.

At the respective pixels in the liquid crystal display device 50 having the above configuration, when a scan signal is supplied from a gate driver (the gate-side TCP 41) to the gate electrode (11a) of the TFT 5a through the gate line 11a, and thereby turns on the TFT 5a, display signals from the source driver (the source-side TCP 42) are supplied to the source electrodes 18aa through the source lines 18a, and prescribed electric charges are written in the pixel electrodes 22a through the semiconductor layers 15a and the drain electrodes 18b. At this time, in the liquid crystal display device 50, a potential difference is created between the respective pixel electrodes 22a in the active matrix substrate 30a and the common electrode 33 of the opposite substrate 40, thereby applying a prescribed voltage to a liquid crystal layer, in other words, to a liquid crystal capacitance of each of the pixels, and to the auxiliary capacitance 6 that is connected in parallel with the liquid crystal capacitance. In each of the pixels in the liquid crystal display device 50, the orientation state of the liquid crystal layer is changed depending on the size of the voltage applied to the liquid crystal layer, and the transmittance of light of the liquid crystal layer is thereby adjusted, making it possible to display images.

Next, a method of manufacturing the liquid crystal display device 50 of the present embodiment will be described using an example with reference to FIGS. 4 to 9 and 18. The manufacturing method of the present embodiment includes fabricating an active matrix substrate, fabricating an opposite substrate, and injecting a liquid crystal.

<Process of Fabricating Active Matrix Substrate>

First, on the entire insulating substrate 10a that is a glass substrate or the like, a titanium film (about 20 nm to 150 nm thick), a copper film (about 200 nm to 500 nm thick), and the like, for example, are laminated in this order by sputtering. Next, this multilayer film is patterned by photolithography, wet etching, resist removing, and washing, thereby forming the gate line (gate electrode) 11a, the capacitance line 11b, and the source line lead-out wiring line 11c as shown in FIGS. 4(a), 6(a), and 8(a).

Next, on the entire substrate having the gate line (gate electrode) 11a, the capacitance line 11b, and the source line lead-out wiring line 11c formed thereon, the gate insulating film 12 formed of a silicon nitride film (about 200 nm to 500 nm thick), an intrinsic amorphous silicon film (about 30 nm to 300 nm thick), an n⁺ amorphous silicon film (about 20 nm to 150 nm thick), and the like, for example, are laminated in this order by the CVD (Chemical Vapor Deposition) method. Thereafter, a multilayer film of the intrinsic amorphous silicon film and the n⁺ amorphous silicon film is patterned by photolithography, dry etching, resist removing, and washing, thereby forming a semiconductor layer 15ab constituted of the intrinsic amorphous silicon layer 13a and an n⁺ amorphous silicon layer 14ab, the semiconductor layer 15b constituted of the intrinsic amorphous silicon layer 13b and the n⁺ amorphous silicon layer 14b, and a semiconductor layer 15ca constituted of an intrinsic amorphous silicon layer 13ca and an n⁺ amorphous silicon layer 14ca, as shown in FIGS. 4(b), 6(b), and 8(b).

Further, on the entire substrate having the semiconductor layers 15ab, 15b, and 15ca formed thereon, a titanium film (about 20 nm to 150 nm thick), an aluminum film (about 100 nm to 400 nm thick), and the like, for example, are laminated in this order by sputtering. Next, this multilayer film is patterned by photolithography and wet etching or dry etching, thereby forming the first conductive layer (titanium layer) 16a and a second conductive layer (aluminum layer) 17aa that form the source line 18a (source electrode 18aa), and the first conductive layer 16b and a second conductive layer (aluminum layer) 17ba that form the drain electrode 18b, as shown in FIGS. 6(c) and 8(c). Thereafter, the n⁺ amorphous silicon layer 14ab that is exposed between the first conductive layer 16a and the second conductive layer (aluminum layer) 17aa and a set of the first conductive layer 16b and a second conductive layer 17ba is removed by dry etching, thereby forming the semiconductor layer 15a (see FIG. 4(c)) constituted of the intrinsic amorphous silicon layer 13a and the n⁺ amorphous silicon layer 14a. Thereafter, a resist removal and washing are performed. In the present embodiment, the aluminum film is given as an example of the conductive film that constitutes the second conductive layer 17aa, but instead of the aluminum film, the second conductive layer 17aa may be constituted of an aluminum alloy or the like. Also, the titanium film is given as an example of the conductive film that constitutes the first conductive layer 16a, but instead of the titanium film, the first conductive layer 16a may be constituted of a molybdenum film, a molybdenum-titanium alloy film, or the like.

Next, the second conductive layers 17aa and 17ba are patterned by photolithography, wet etching, resist removing, and washing, thereby forming the second conductive layers 17ab and 17bb. As a result, the source line 18a (source electrode 18aa) constituted of the first conductive layer 16a and the second conductive layer 17ab, the drain electrode 18b constituted of the first conductive layer 16b and the second conductive layer 17bb, and the TFT 5a are formed, as shown in FIGS. 4(c), 6(d), and 8(d). In the present embodiment, a method in which the step of removing part of the second conductive layer is performed after patterning the multilayer film of the titanium film and the aluminum film is described as an example. Instead, the step of removing part of the second conductive layer may be performed before patterning the multilayer film of the titanium film and the aluminum film.

On the entire substrate having the TFT 5a formed thereon, a silicon nitride film (about 100 nm to 700 nm thick), for example, is deposited by the CVD method, thereby forming an inorganic insulating film 19 as shown in FIGS. 4(d), 6(e), and 8(e).

Next, on the entire substrate having the inorganic insulating film 19 formed thereon, a photosensitive organic insulating film is applied with the thickness of about 1.0 μm to 3.0 μm, for example, by the spin coating method. Thereafter, the photosensitive organic insulating film is exposed and developed, thereby forming the second interlayer insulating film 20 that has the contact holes 21a and 21b as shown in FIGS. 7(a) and 9(a).

Further, the inorganic insulating film 19 that is exposed from the second interlayer insulating film 20 is removed by dry etching, thereby forming the first interlayer insulating film 19a, and then forming the interlayer insulating film 21 that is constituted of the first interlayer insulating film 19a and the second interlayer insulating film 20 as shown in FIGS. 5(a), 7(b), and 9(b). Here, an edge of the semiconductor layer 15ca that is exposed from the first interlayer insulating film 19a is also removed, and as shown in FIG. 9(b), the semiconductor layer 15c that is constituted of the intrinsic amorphous silicon layer 13c and the n⁺ amorphous silicon layer 14c is formed. In the present embodiment, the interlayer insulating film 21, which is a multilayer film of the first interlayer insulating film 19a and the second interlayer insulating film 20, is given as an example. Alternatively, a single layer film, which is the first interlayer insulating film 19a or the second interlayer insulating film 20, may be used.

Lastly, on the entire substrate having the interlayer insulating film 21 formed thereon, a transparent conductive film such as an ITO film (about 50 nm to 200 nm thick), for example, is deposited by sputtering. Thereafter, the transparent conductive film is patterned by photolithography, wet etching, resist removing, and washing, thereby forming the pixel electrode 22a and the transparent conductive layer 22b as shown in FIGS. 5(b), 7(c), and 9(c).

The active matrix substrate 30a can be fabricated in the above-mentioned manner.

<Process of Fabricating Opposite Substrate>

First, on the entire insulating substrate 10b that is a glass substrate or the like, a photosensitive resin that is colored black, for example, is applied by the spin coating method. Next, the photosensitive resin film is exposed and developed, thereby forming the black matrix 31 (see FIG. 18(a)) with a thickness of about 1.0 μm.

Next, on the entire substrate having the black matrix 31 formed thereon, a photosensitive resin that is colored red, green, or blue, for example, is applied by the spin coating method. Thereafter, the photosensitive resin film is exposed and developed, thereby forming the colored layers 32 of a selected color (red layers, for example) with a thickness of about 2.0 μm as shown in FIG. 18(a). The same process is repeated for the other two colors, thereby forming the respective colored layers 32 of the other two colors (green layers and blue layers, for example) with a thickness of about 2.0 μm.

On the substrate having the colored layers 32 of the respective colors formed thereon, a transparent conductive film such as an ITO film, for example, is deposited by sputtering, thereby forming the common electrode 33 with a thickness of about 50 nm to 200 nm as shown in FIG. 18(b).

Lastly, on the entire substrate having the common electrode 33 formed thereon, a photosensitive resin is applied by the spin coating method. Thereafter, the photosensitive resin film is exposed and developed, thereby forming the photospacer 34 with a thickness of about 4 μm as shown in FIG. 18(c).

The opposite substrate 40 can be fabricated in the manner described above.

<Process of Injecting Liquid Crystal>

First, on the surface of the active matrix substrate 30a that is fabricated by the process of fabricating the active matrix substrate, and on the surface of the opposite substrate 40 that is fabricated by the process of fabricating the opposite substrate, polyimide resin films are applied by the printing method. Thereafter, a baking process and a rubbing process are performed on the polyimide resin films, thereby forming the alignment films.

Next, on the surface of the opposite substrate 40 on which the alignment film is formed, a sealing material that is constituted of a UV- (ultraviolet-) curable and thermosetting resin or the like is printed in a frame shape, for example, and a liquid crystal material is dripped inside of the sealing material.

The opposite substrate 40 on which the liquid crystal material is dripped and the active matrix substrate 30a on which the alignment film is formed are bonded under the reduced pressure. Thereafter, the bonded laminated body is exposed to the atmospheric pressure such that a pressure is applied to the front surface and to the rear surface of the laminated body.

Next, the sealing material is cured by radiating UV light to the sealing material sandwiched by the laminated body, and by heating the laminated body thereafter.

Lastly, the laminated body in which the sealing material has been cured is cut by dicing, for example, and after removing unnecessary portions, the gate-side TCPs 41, the source-side TCPs 42, and the like are mounted on the terminal region T of the active matrix substrate 30a.

The liquid crystal display device 50 of the present embodiment can be manufactured in the manner described above.

As described above, according to the active matrix substrate 30a of the present embodiment, in the drain electrodes 18b, each of which is formed by laminating the first conductive layer 16b and the second conductive layer 17bb in this order, at a side thereof connected to the respective pixel electrodes 22a, the top surface of the first conductive layer 16b is exposed from the second conductive layer 17bb, and the second conductive layer 17bb is covered by the interlayer insulating film 21. Therefore, the second conductive layer 17bb does not come into contact with the pixel electrodes 22a, thereby suppressing a possible electric corrosion reaction between the drain electrodes 18b and the pixel electrodes 22a. Also, because the second conductive layer 17bb that constitutes the drain electrodes 18b is covered by the interlayer insulating film 21, even when the active matrix substrate is used to constitute a liquid crystal display device together with the opposite substrate 40 and the liquid crystal layer made of the liquid crystal material, the second conductive layer 17bb can be prevented from being exposed to the liquid crystal material, thereby suppressing corrosion of the second conductive layer 17bb. As a result, it is possible to suppress an electric corrosion reaction between the drain electrodes 18b and the pixel electrodes 22a, and also, to suppress corrosion of the second conductive layer 17bb. Therefore, in the active matrix substrate 30a, an electric corrosion reaction can be suppressed, and also, corrosion of the drain electrodes 18b can be suppressed. Because the formation of an overhang in an eaves shape in an inner wall of the contact hole 21a of the interlayer insulating film 21 is prevented, disconnected areas in the pixel electrodes 22a can be reduced, thereby further ensuring the connection between the drain electrodes 18b and the pixel electrodes 22a.

According to the active matrix substrate 30a of the present embodiment, in the source line 18a that is formed of the same material and is disposed on the same layer as those of the source electrode 18aa and the drain electrode 18b (i.e., the source line 18a is formed by depositing the first conductive layer 16a and the second conductive layer 17ab in this order), at a side thereof connected to the transparent conductive layer 22b, the top surface of the first conductive layer 16a is exposed from the second conductive layer 17ab, and the second conductive layer 17ab is covered by the interlayer insulating film 21. Therefore, the second conductive layer 17ab does not come into contact with the transparent conductive layer 22b, and as a result, a possible electric corrosion reaction in the connection structure of the source line lead-out wiring line 11c and the source line 18a through the transparent conductive layer 22b can be suppressed. Also, because the second conductive layer 17ab that constitutes the source line 18a is covered by the interlayer insulating film 21, the second conductive layer 17ab can be prevented from being exposed to the air, thereby suppressing corrosion of the second conductive layer 17ab. As a result, it is possible to suppress an electric corrosion reaction caused by the source line 18a, and also, it is possible to suppress corrosion of the source line 18a. Because the formation of an overhang in an eaves shape on the inner wall of the contact hole 21b of the interlayer insulating film 21 is prevented, disconnected areas in the transparent conductive layer 22b can be reduced, thereby further ensuring the connection between the source line lead-out wiring line 11c and the source line 18a. Further, patterning of the second conductive layer (aluminum layer) 17aa is performed separately from forming the contact hole 21b. Therefore, it is possible to dispose a conductive film such as a copper film, which has a low resistance against an etchant for the aluminum film, on the source line lead-out wiring line 11c.

According to the active matrix substrate 30a of the present embodiment, the semiconductor layer (etching stopper layer) 15b formed of the same material and disposed on the same layer as those of the semiconductor layer 15a is disposed between the gate insulating film 12 and the connecting portions of the drain electrode 18b and each pixel electrode 22a. Therefore, when the contact hole 21a is formed in the multilayer film of the gate insulating film 12 and the interlayer insulating film 21, the gate insulating film 12 is less likely to be exposed to etching. As a result, a short circuit problem at the auxiliary capacitance that is constituted of the capacitance line 11b, the drain electrode 18b, and the gate insulating film 12 formed therebetween can be suppressed.

According to the active matrix substrate 30a of the present embodiment, the interlayer insulating film 21 is provided with the first interlayer insulating film 19a that is formed relatively thin using the inorganic insulating film, and the second interlayer insulating film 20 that is formed relatively thick on the first interlayer insulating film 19a using the organic insulating film. Therefore, the top surface of the interlayer insulating film 21 can be planarized.

### Embodiment 2

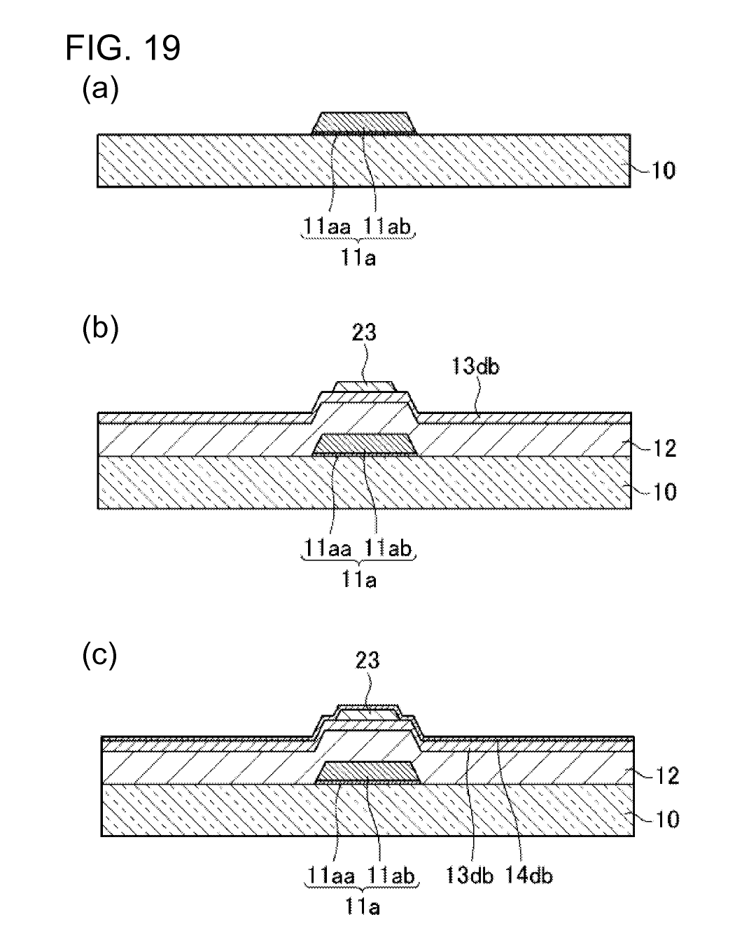

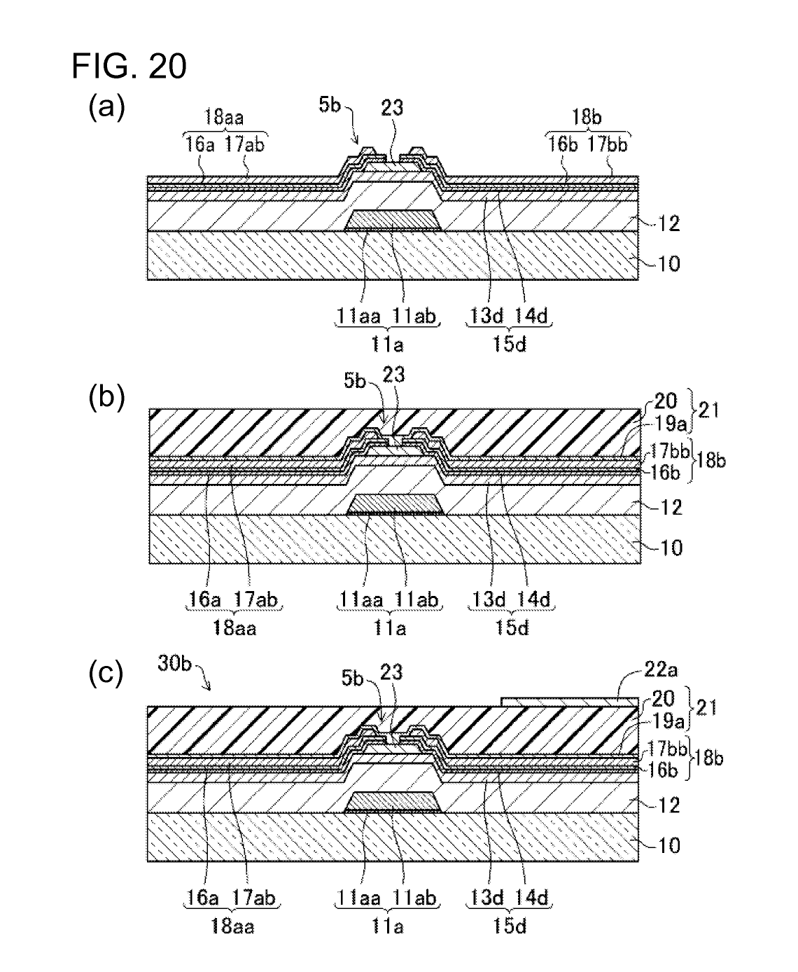

FIGS. 19 and 20 are explanatory figures showing a process of manufacturing an active matrix substrate 30b of the present embodiment in a cross-sectional view. In each embodiment below, the same members as those in FIGS. 1 to 18 are given the same reference characters, and the description thereof will not be repeated.

In Embodiment 1, the active matrix substrate 30a provided with the TFT 5a in which a channel protecting layer is not disposed was described as an example. In the present embodiment, the active matrix substrate 30b provided with a TFT 5b in which a channel protecting layer 23 is disposed will be described as an example.

As shown in FIG. 20(c), the active matrix substrate 30b has substantially the same configuration as that of the active matrix substrate 30a in Embodiment 1, except that the channel protecting layer 23 is disposed between an intrinsic amorphous silicon layer 13d and an n⁺ amorphous silicon layer 14d that constitute a semiconductor layer 15d.

Next, a method of manufacturing the active matrix substrate 30b of the present embodiment will be described using an example with reference to FIGS. 19 and 20.

First, on the entire insulating substrate 10a that is a glass substrate or the like, a titanium film (about 30 nm to 150 nm thick), a copper film (about 200 nm to 500 nm thick), and the like, for example, are laminated in this order by sputtering. Next, this multilayer film is patterned by photolithography, wet etching, resist removing, and washing, thereby forming the gate electrode 11a constituted of a titanium layer 11aa and a copper layer 11ab as shown in FIG. 19(a).

Next, on the entire substrate having the gate electrode 11a formed thereon, the gate insulating film 12 formed of a silicon nitride film (about 200 nm to 500 nm thick), an intrinsic amorphous silicon film 13db (about 30 nm to 300 nm thick), a silicon nitride film (about 100 nm to 300 nm thick), and the like, for example, are laminated in this order by the CVD method. Thereafter, the upper silicon nitride film is patterned by photolithography, dry etching, resist removing, and washing, thereby forming the channel protecting layer 23 as shown in FIG. 19(b).

On the entire substrate having the channel protecting layer 23 formed thereon, an n⁺ amorphous silicon film 14db (about 50 nm to 150 nm thick; see FIG. 19(c)), for example, is deposited by the CVD method, and then a titanium film (about 30 nm to 150 nm thick), an aluminum film (about 100 nm to 400 nm thick), and the like, for example, are laminated in this order by sputtering. Thereafter, as shown in FIG. 20(a), a multilayer film of the intrinsic amorphous silicon film 13db, the n⁺ amorphous silicon film 14db, the titanium film, and the aluminum film is patterned by photolithography, wet etching, dry etching, resist removing, and washing, thereby forming the source electrode 18aa constituted of the first conductive layer 16a and the second conductive layer 17ab, the drain electrode 18b constituted of the first conductive layer 16b and the second conductive layer 17bb, the semiconductor layer 15d constituted of the intrinsic amorphous silicon layer 13d and the n⁺ amorphous silicon layer 14d, and the TFT 5b. When forming the source electrode 18aa and the drain electrode 18b, in the same manner as Embodiment 1, the first conductive layer (titanium layer) 16a and the second conductive layer 17aa, which form the source electrode 18aa, and the first conductive layer 16b and the second conductive layer 17ba, which form the drain electrode 18b, are first formed, and thereafter, the second conductive layers 17aa and 17ba are patterned through photolithography, wet etching, resist removing, and washing, thereby forming the second conductive layers 17ab and 17bb.

On the entire substrate having the TFT 5b formed thereon, a silicon nitride film (about 100 nm to 700 nm thick), for example, is deposited by the CVD method, thereby forming the inorganic insulating film 19. Next, a photosensitive organic insulating film, for example, is applied with a thickness of about 1.0 μm to 3.0 μm by the spin coating method, and thereafter, the photosensitive organic insulating film is exposed and developed, thereby forming the second interlayer insulating film 20 that has contact holes. Thereafter, the inorganic insulating film 19 that is exposed from the second interlayer insulating film 20 is removed by dry etching, thereby forming the first interlayer insulating film 19a as shown in FIG. 20(b), and then forming the interlayer insulating film 21 that is constituted of the first interlayer insulating film 19a and the second interlayer insulating film 20.

Lastly, on the entire substrate having the interlayer insulating film 21 formed thereon, a transparent conductive film such as an ITO film (about 50 nm to 200 nm thick), for example, is deposited by sputtering. Thereafter, the transparent conductive film is patterned by photolithography, wet etching, resist removing, and washing, thereby forming the pixel electrode 22a as shown in FIG. 20(c).

The active matrix substrate 30b can be manufactured in the manner described above.

As described above, according to the active matrix substrate 30b of the present embodiment, in the same manner as Embodiment 1, in the drain electrodes 18b, each of which is formed by laminating the first conductive layer 16b and the second conductive layer 17bb in this order, at a side thereof connected to the respective pixel electrodes 22a, the top surface of the first conductive layer 16b is exposed from the second conductive layer 17bb, and the second conductive layer 17bb is covered by the interlayer insulating film 21. Therefore, in the active matrix substrate 30b, it is possible to suppress an electric corrosion reaction, and also to suppress corrosion of the drain electrodes 18b.

### Embodiment 3

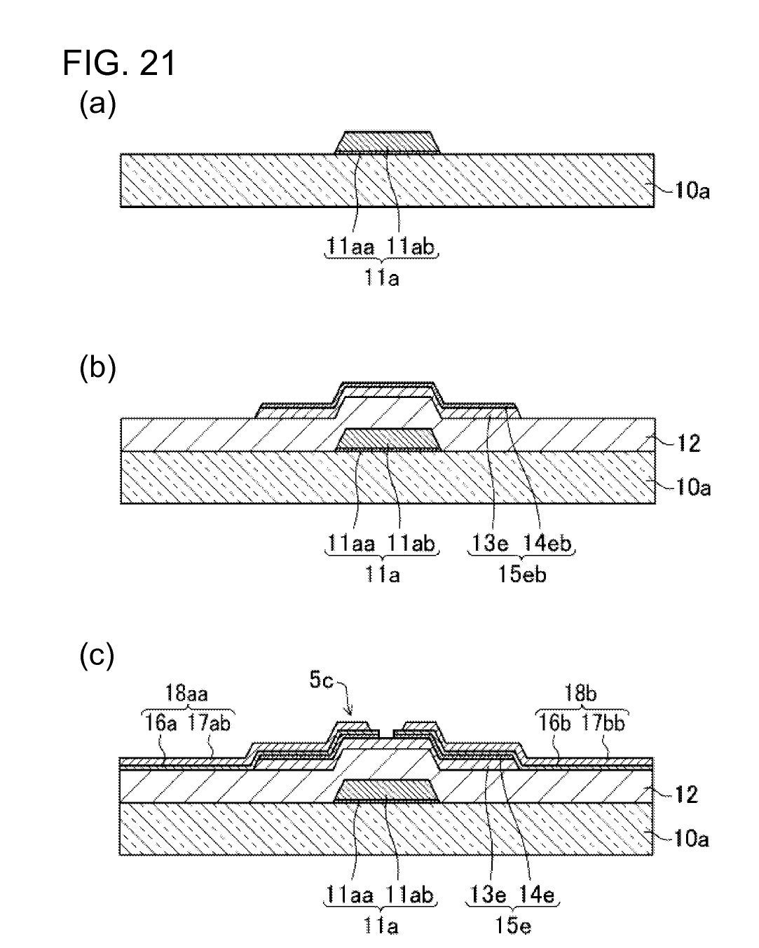

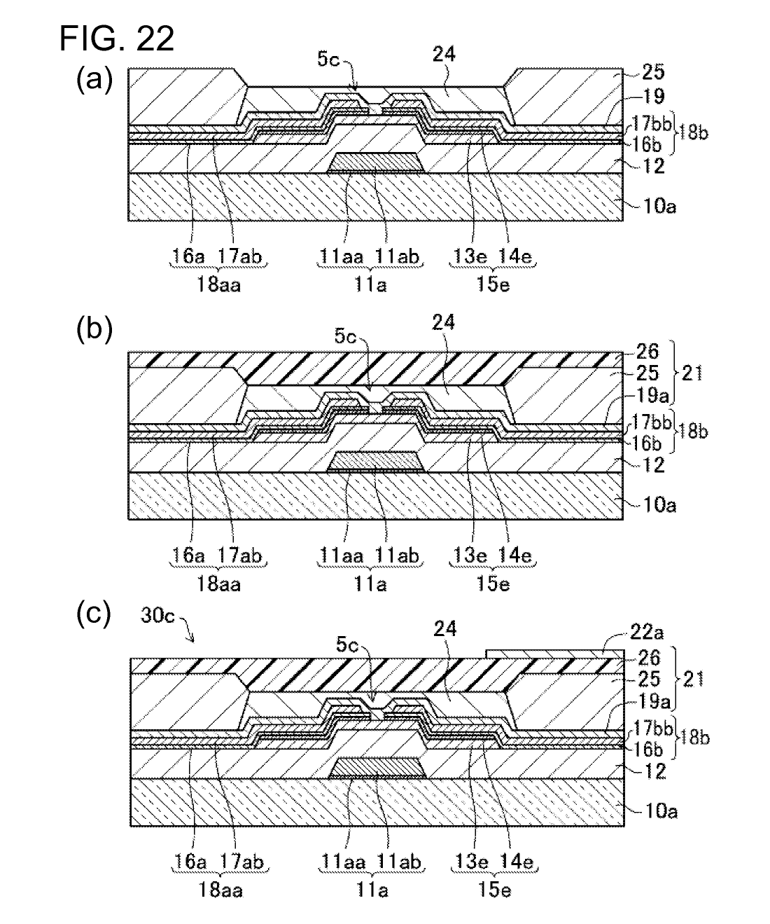

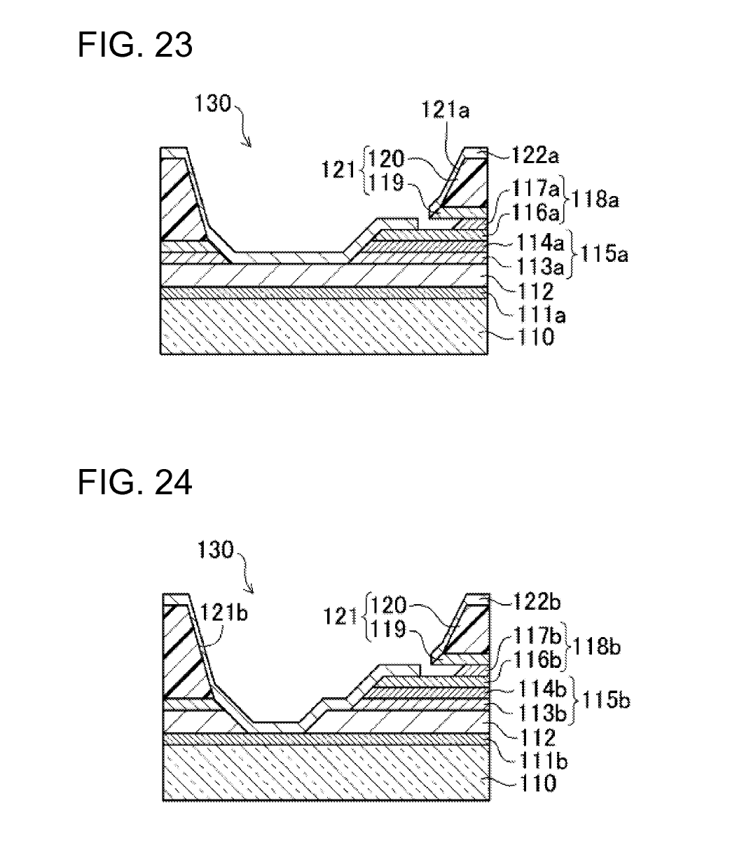

FIGS. 21 and 22 are explanatory figures showing a process of manufacturing an active matrix substrate 30c of the present embodiment in a cross-sectional view.

In Embodiments 1 and 2, the active matrix substrates 30a and 30b in the case where the color filters are disposed on the opposite substrate were described as examples, respectively. In the present embodiment, the active matrix substrate 30c that has a so-called color filter on array structure, in which the color filters are disposed on the active matrix substrate, will be described as an example.

As shown in FIG. 22(c), in the active matrix substrate 30c, instead of the second interlayer insulating film 20 in the active matrix substrate 30a of Embodiment 1, a black matrix 24, colored layers 25, and a third interlayer insulating film 26 that covers the black matrix 24 and the colored layers 25 are disposed. Other structures of the active matrix substrate 30c are substantially the same as those of the active matrix substrate 30a.

Next, the method of manufacturing the active matrix substrate 30c of the present embodiment will be described using an example with reference to FIGS. 21 and 22.

First, on the entire insulating substrate 10a that is a glass substrate or the like, a titanium film (about 30 nm to 150 nm thick), a copper film (about 200 nm to 500 nm thick), and the like, for example, are laminated in this order by sputtering. Next, this multilayer film is patterned by photolithography, wet etching, resist removing, and washing, thereby forming the gate electrode 11a constituted of the titanium layer 11aa and the copper layer 11ab as shown in FIG. 21(a).

Next, on the entire substrate having the gate electrode 11a formed thereon, the gate insulating film 12 formed of a silicon nitride film (about 200 nm to 500 nm thick), an intrinsic amorphous silicon film (about 30 nm to 300 nm thick), an n⁺ amorphous silicon film (about 20 nm to 150 nm thick), and the like, for example, are laminated in this order by the CVD method. Thereafter, a multilayer film of the intrinsic amorphous silicon film and the n⁺ amorphous silicon film is patterned by photolithography, dry etching, resist removing, and washing, thereby forming a semiconductor layer 15eb constituted of an intrinsic amorphous silicon layer 13e and an n⁺ amorphous silicon layer 14eb as shown in FIG. 21(b).

Further, on the entire substrate having the semiconductor layer 15eb formed thereon, a titanium film (about 20 nm to 150 nm thick), an aluminum film (about 100 nm to 400 nm thick), and the like, for example, are laminated in this order by sputtering. Next, this multilayer film is patterned by photolithography, wet etching, dry etching, resist removing, and washing, thereby forming the source electrode 18aa constituted of the first conductive layer 16a and the second conductive layer 17ab, and the drain electrode 18b constituted of the first conductive layer 16b and the second conductive layer 17bb. Next, the n⁺ amorphous silicon layer 14eb that is exposed between the source electrode 18aa and the drain electrode 18b is removed by dry etching, thereby forming a semiconductor layer 15e constituted of the intrinsic amorphous silicon layer 13e and an n⁺ amorphous silicon layer 14e, and forming a TFT 5c as shown in FIG. 21(c). When forming the source electrode 18aa and the drain electrode 18b, in the same manner as Embodiment 1, the first conductive layer (titanium layer) 16a and the second conductive layer 17aa, which form the source electrode 18aa, and the first conductive layer 16b and the second conductive layer 17ba, which form the drain electrode 18b, are first formed, and thereafter, the second conductive layers 17aa and 17ba are patterned through photolithography, wet etching, resist removing, and washing, thereby forming the second conductive layers 17ab and 17bb.

On the entire substrate having the TFT 5c formed thereon, a silicon nitride film (about 100 nm to 700 nm thick), for example, is deposited by the CVD method, thereby forming the inorganic insulating film 19 (see FIG. 22(a)). Further, a photosensitive resin that is colored black, for example, is applied by the spin coating method, and thereafter, the photosensitive resin film is exposed and developed, thereby forming the black matrix 24 (see FIG. 22(a)) with a thickness of about 1.0 μm.

Next, on the entire substrate having the black matrix 24 formed thereon, a photosensitive resin that is colored red, green, or blue, for example, is applied by the spin coating method. Thereafter, the photosensitive resin film is exposed and developed, thereby forming the colored layer 25 of a selected color (a red layer, for example) with a thickness of about 2.0 μm as shown in FIG. 22(a). The same process is repeated for the other two colors, thereby forming the respective colored layers 25 of the other two colors (a green layer and a blue layer, for example) with a thickness of about 2.0 μm.

Further, on the substrate having the colored layers 25 of the respective colors formed thereon, a photosensitive organic insulating film, for example, is applied with a thickness of about 1.0 μm to 3.0 μm by the spin coating method. Next, the photosensitive organic insulating film is exposed and developed, thereby forming the third interlayer insulating film 26 that has contact holes. Thereafter, the colored layers 25 and the inorganic insulating film 19 that are exposed from the third interlayer insulating film 26 are removed by dry etching, thereby forming the first interlayer insulating film 19a, and forming the interlayer insulating film 21 that is constituted of the first interlayer insulating film 19a, the black matrix 24, the colored layers 25, and the third interlayer insulating film 26 as shown in FIG. 22(b).

Lastly, on the entire substrate having the interlayer insulating film 21 formed thereon, a transparent conductive film such as an ITO film (about 50 nm to 200 nm thick), for example, is deposited by sputtering. Thereafter, the transparent conductive film is patterned by photolithography, wet etching, resist removing, and washing, thereby forming the pixel electrode 22a as shown in FIG. 22(c).

The active matrix substrate 30c can be manufactured in the manner described above.

The opposite substrate disposed so as to face the active matrix substrate 30c can be manufactured as follows: on the entire insulating substrate that is a glass substrate or the like, for example, a transparent conductive film such as an ITO film is deposited with a thickness of about 50 nm to 200 nm by sputtering, thereby forming a common electrode; next, on the entire substrate having the common electrode formed thereon, a photosensitive resin is applied by the spin coating method; and thereafter, the photosensitive resin film is exposed and developed, thereby forming a photospacer with a thickness of about 4 μm.

As described above, according to the active matrix substrate 30c of the present embodiment, in the same manner as each of the embodiments described above, in the same manner as Embodiments 1 and 2, in the drain electrodes 18b, each of which is formed by laminating the first conductive layer 16b and the second conductive layer 17bb in this order, on the side thereof connected to the respective pixel electrodes 22a, the top surface of the first conductive layer 16b is exposed from the second conductive layer 17bb, and the second conductive layer 17bb is covered by the interlayer insulating film 21. Therefore, in the active matrix substrate 30c, it is possible to suppress an electric corrosion reaction, and it is also possible to suppress corrosion of the drain electrode 18b.

In the present embodiment, a configuration in which the color filter on array structure is applied to the active matrix substrate 30a of Embodiment 1, which does not have the channel protecting layer, was described as an example. Instead, a configuration in which a color-filter on array structure is applied to the active matrix substrate 30b of Embodiment 2, which has the channel protecting layer, may be employed.

In each of the embodiments described above, the gate line that has a multilayer structure of the copper film and the titanium film, and the source line that has a multilayer structure of the aluminum film and the titanium film were described as an example. The present invention is particularly effective when the respective upper conductive films that constitute the gate line and the source line, respectively, are susceptible to corrosion, and are mutually different.

In each of the embodiments described above, the manufacturing method in which the step of forming the amorphous silicon semiconductor layer is separated from the step of forming the source line was described as an example. The present invention can be also applied to an active matrix substrate that is manufactured by a manufacturing method that employs the technique of forming a resist with two or more different thicknesses by performing exposure and development using a halftone mask and the technique of making the resist reduced and receded by resist removal, such that the semiconductor layer and the source line can be formed through a single photolithography and etching.

In each of the embodiments described above, the active matrix substrate that uses the amorphous silicon semiconductor layer was described as an example. The present invention can be also applied to an active matrix substrate that uses a semiconductor layer formed of an oxide such as ZnO or IGZO (In—Ga—Zn—O).

In each of the embodiments described above, the liquid crystal display device provided with the active matrix substrate was described as an example of the display device. The present invention can be also applied to other display devices such as an organic EL (Electro Luminescence) display device, an inorganic EL display device, and an electrophoresis display device.

In each of the embodiments described above, the active matrix substrate in which the electrode of the TFT that is connected to the pixel electrode is used as the drain electrode was described as an example. The present invention can be also applied to an active matrix substrate in which an electrode of a TFT that is connected to a pixel electrode is referred to as a source electrode.

### INDUSTRIAL APPLICABILITY

As described above, the present invention can suppress an electric corrosion reaction, and can also suppress corrosion of the drain electrode. Therefore, the present invention is effective for an active matrix substrate that uses a conductive film containing aluminum, and an ITO film, for example.

### DESCRIPTION OF REFERENCE CHARACTERS

5a, 5b, 5c TFT
10a insulating substrate
11a gate electrode
11b capacitance line
11c source line lead-out wiring line (first wiring line) gate insulating film
15a semiconductor layer
15b etching stopper layer
16a, 16b first conductive layer
17ab, 17bb second conductive layer
18a source line (second wiring line)
18aa source electrode
18b drain electrode
19a first interlayer insulating film
20 second interlayer insulating film
21 interlayer insulating film
21a, 21b contact hole
22a pixel electrode
22b transparent conductive layer
30a, 30b, 30c active matrix substrate

1. An active matrix substrate, comprising:
a plurality of thin film transistors disposed on an insulating substrate in a matrix, each of which has a source electrode and a drain electrode formed by laminating a first conductive layer and a second conductive layer in this order;
an interlayer insulating film that is deposited on the respective thin film transistors, the interlayer insulating film having a plurality of contact holes, each of which reach to a corresponding drain electrode, formed therein; and
a plurality of pixel electrodes disposed on the interlayer insulating film in a matrix, each of which is connected to a corresponding drain electrode via said contact hole, the plurality of pixel electrodes being susceptible to an electric corrosion reaction with the second conductive layer,
wherein, at a side of each said drain electrode, which is connected to a corresponding pixel electrode, a top surface of the first conductive layer is exposed from the second conductive layer, and
wherein the interlayer insulating film is disposed so as to cover the second conductive layer.

2. The active matrix substrate according to claim 1,
wherein the second conductive layer is formed of an aluminum film or an aluminum alloy film, and
wherein the respective pixel electrodes are formed of an ITO (Indium Tin Oxide) film.

3. The active matrix substrate according to claim 1, comprising:
a gate electrode disposed in each said thin film transistor so as to overlap the source electrode and the drain electrode; a first wiring line formed of a same material and disposed in a same layer as those of the gate electrode; a gate insulating film disposed so as to cover the first wiring line; and a second wiring line formed of a same material and disposed in a same layer as those of the source electrode and the drain electrode,
wherein the first wiring line and the second wiring line are connected through a transparent conductive layer that is formed of a same material and is disposed in a same layer as those of the respective pixel electrodes, the transparent conductive layer being formed in a contact hole formed in a multilayer film of the gate insulating film and the interlayer insulating film,
wherein, at a side of the second wiring line, which is connected to the transparent conductive layer, a top surface of the first conductive layer is exposed from the second conductive layer, and
wherein the interlayer insulating film is disposed so as to cover the second conductive layer on the second wiring line.

4. The active matrix substrate according to claim 3,
wherein the second wiring line is a source line that is connected to a corresponding source electrode; and
wherein the first wiring line is a source line lead-out wiring line that is connected to the source line.

5. The active matrix substrate according to claim 3, comprising:
a semiconductor layer disposed in each said thin film transistor so as to overlap the gate electrode through the gate insulating film, the semiconductor layer also overlapping the source electrode and the drain electrode; and a capacitance line formed of a same material and disposed on a same layer as those of the gate electrode, the capacitance line overlapping a connecting portion of the drain electrode and each said pixel electrode through the gate insulating film,
wherein, between the gate insulating film and the connecting portion of the drain electrode and each said pixel electrode, an etching stopper layer is formed of a same material and is disposed in a same layer as those of the semiconductor layer.

6. The active matrix substrate according to claim 1,
wherein the interlayer insulating film comprises a first interlayer insulating film formed of an inorganic insulating film, and a second interlayer insulating film formed of an organic insulating film on the first interlayer insulating film.
